(19) United States
(12) Patent Application Publication
(10) Pub. No.: US 2023/0163178 A1
(43) Pub. Date: May 25, 2023

(54) SEMICONDUCTOR DEVICES

(71) Applicant: Samsung Electronics Co., Ltd., Suwon-si (KR)

(72) Inventor: Sungmin KIM, Incheon (KR)

(73) Assignee: Samsung Electronics Co., Ltd., Suwon-si (KR)

(21) Appl. No.: 17/887,600

(22) Filed: Aug. 15, 2022

(30) Foreign Application Priority Data
Nov. 25, 2021 (KR) 10-2021-0164616

(51) Int. Cl. H01L 29/417; H01L 29/06; H01L 29/08; H01L 29/423; H01L 29/786; H01L 29/775; H01L 29/40; H01L 29/66

(52) U.S. Cl. CPC H01L 29/41733; H01L 29/0673; H01L 29/0847; H01L 29/42392; H01L 29/78696; H01L 29/775; H01L 29/401; H01L 29/66553; H01L 29/66545; H01L 29/66742; H01L 29/66439

(57) ABSTRACT

A semiconductor device includes a buried interconnection line extending in a first direction, a gate electrode extending in a second direction intersecting the buried interconnection line, and channel layers spaced apart from each other in a third direction perpendicular to the first direction and the second direction. The channel layers are surrounded by the gate electrode, and the buried interconnection line includes a metal layer and a semiconductor layer stacked in the third direction. The device includes a buried insulating layer between the channel layers and the buried interconnection line, and first and second source/drain regions in contact with the channel layers on both sides of the gate electrode. The second source/drain region penetrates through the buried insulating layer and is in contact with the semiconductor layer. The device includes a contact plug on the first source/drain region, and a via below the buried interconnection line.

### CROSS-REFERENCE TO RELATED APPLICATION

This U.S. non-provisional patent application claims priority under 35 U.S.C. § 119 to Korean Patent Application No. 10-2021-0164616 filed on Nov. 25, 2021 in the Korean Intellectual Property Office, the disclosure of which is incorporated herein by reference in its entirety.

### BACKGROUND

Some example embodiments of the inventive concepts relate to a semiconductor device.

As a demand for high performance, high speed and/or multifunctionality of semiconductor devices, or the like, is increased, a degree of integration of semiconductor devices is increasing. In manufacturing a semiconductor device having a fine pattern, corresponding to a tendency for high integration of semiconductor devices, it may be advantageous to implement patterns having a fine width or a fine spacing distance. In addition, to overcome limitations of operating characteristics due to reductions in the size of a planar metal oxide semiconductor FET (MOSFET), efforts have been made to develop a semiconductor device including a FinFET having a channel including a three-dimensional structure.

### SUMMARY

Some example embodiments of the inventive concepts provide a semiconductor device having an improved degree of integration and improved electrical characteristics.

According to some example embodiments of the inventive concepts, a semiconductor device includes a buried interconnection line extending in a first direction, and a gate electrode extending in a second direction intersecting the buried interconnection line. The gate electrode is on the buried interconnection line. The device includes channel layers spaced apart from each other in a third direction perpendicular to the first direction and the second direction. The channel layers are on the buried interconnection line and surrounded by the gate electrode, and the buried interconnection line includes a metal layer and a semiconductor layer stacked in the third direction. The device includes a buried insulating layer between the channel layers and the buried interconnection line, a first source/drain region and a second source/drain region. The first and second source/drain regions are in contact with the channel layers on both sides of the gate electrode, and the second source/drain region penetrates through the buried insulating layer and is in contact with the semiconductor layer of the buried interconnection line. The device includes a contact plug on the first source/drain region, and connected to the first source/drain region, and a via below the buried interconnection line and connected to the buried interconnection line.

According to some example embodiments of the inventive concepts, a semiconductor device includes a buried interconnection line extending in a first direction, a buried insulating layer on the buried interconnection line, an active structure on the buried insulating layer, and a gate electrode extending in a second direction intersecting the active structure. The gate electrode is on the buried insulating layer. The device includes a first source/drain region and a second source/drain region. The first and second source/drain regions are on both sides of the gate electrode in regions where the active structure is recessed, and the buried interconnection line includes a semiconductor layer extending in the first direction and in contact with the second source/drain region.

According to some example embodiments of the inventive concepts, Aa semiconductor device includes a buried interconnection line extending in a first direction, a buried insulating layer on the buried interconnection line, and a gate electrode extending in a second direction intersecting the first direction. The gate electrode is on the buried insulating layer. The device includes channel layers spaced apart from each other in a third direction perpendicular to the first direction and the second direction. The channel layers are on the buried insulating layer, and surrounded by the gate electrode. The device includes source/drain regions disposed on both sides of the gate electrode. The buried interconnection line overlaps the channel layers in the third direction, and is connected to a portion of the source/drain regions below the source/drain regions.

### BRIEF DESCRIPTION OF DRAWINGS

Some example embodiments of the inventive concepts may be more clearly understood from the following detailed description, taken in conjunction with the accompanying drawings, in which:

FIG. 1 is a plan view illustrating a semiconductor device according to some example embodiments;

FIGS. 2A, 2B and 2C are cross-sectional views illustrating semiconductor devices according to some example embodiments;

FIGS. 3A and 3B are schematic cross-sectional views illustrating semiconductor devices according to some example embodiments;

FIGS. 4A and 4B are schematic cross-sectional views illustrating semiconductor devices according to some example embodiments;

FIG. 5 is a schematic cross-sectional view illustrating a semiconductor device according to some example embodiments;

FIGS. 6A and 6B are cross-sectional views illustrating semiconductor devices according to some example embodiments; and

FIGS. 7A, 7B, 7C, 7D, 7E, 7F, 7G, 7H, 7I and 7J are diagrams illustrating a process sequence in order to explain a method of manufacturing a semiconductor device according to some example embodiments.

### DETAILED DESCRIPTION

Hereinafter, some example embodiments of the inventive concepts will be described with reference to the accompanying drawings. Herein, terms such as ‘an upper side, ‘an upper portion’, ‘an upper surface’, a lower side, a lower portion, a lower surface, and the like, may be understood as referring to the drawings, except where otherwise indicated by reference numerals.

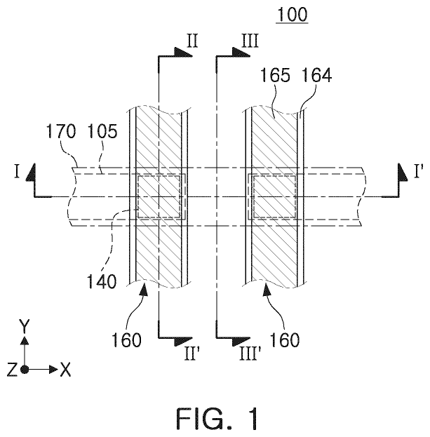

FIG. 1 is a plan view illustrating a semiconductor device according to some example embodiments.

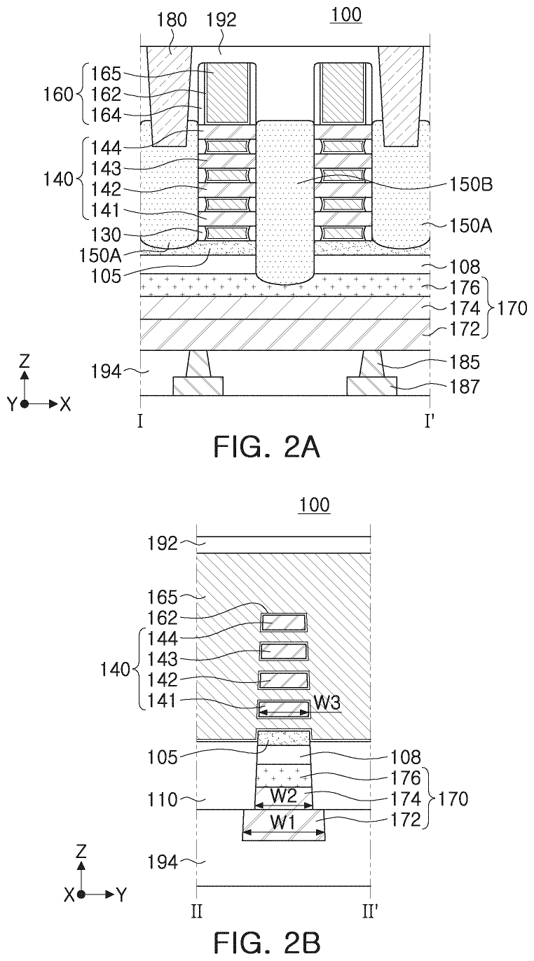

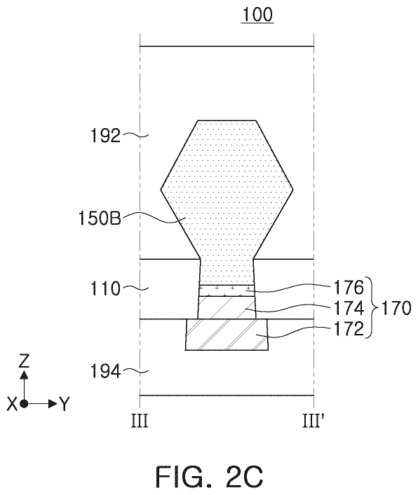

FIGS. 2A to 2C are cross-sectional views illustrating semiconductor devices according to some example embodiments. FIGS. 2A to 2C illustrate cross-sections of the semiconductor device of FIG. 1 taken along cutting lines I-I′, II-II′, and III-III′, respectively. For convenience of description, only some components of the semiconductor device are illustrated in FIG. 1.

Referring to FIGS. 1 to 2C, the semiconductor device 100 may include a buried interconnection line 170, a buried insulating layer 108 on the buried interconnection line 170, an active layer 105 on the buried insulating layer 108, gate structures 160 extending to cross the buried interconnection line 170 and the active layer 105, channel structures 140 including first to fourth channel layers 141, 142, 143, and 144 disposed on the active layer 105 to be vertically spaced apart from each other, first and second source/drain regions 150A and 150B disposed on both sides of the gate structures 160 to be in contact with the channel structures 140, contact plugs 180 connected to the first source/drain regions 150A, and vias 185 connected to the buried interconnection line 170. The semiconductor device 100 may further include a device isolation layer 110, internal spacer layers 130, interconnection lines 187, and first and second interlayer insulating layers 192 and 194. The gate structure 160 may include gate dielectric layers 162, gate spacer layers 164, and a gate electrode 165.

In the semiconductor device 100, the gate electrode may be disposed between the active layer 105 and the channel structures 140, between the first to fourth channel layers 141, 142, 143, and 144 of the channel structure 140, and above the channel structures. Accordingly, the semiconductor device 100 may include a transistor having a multi-bridge channel FET (MBCFET™) structure, which is a gate-all-around field effect transistor.

The buried interconnection line 170 may be disposed to extend in a first direction, for example, an X-direction. The buried interconnection line 170 may be a power interconnection line for applying power or a ground voltage, and may also be referred to as a buried power rail. The buried interconnection line 170 may include a first metal layer 172, a second metal layer 174, and a semiconductor layer 176 sequentially stacked from the bottom. Each of first metal layer 172, the second metal layer 174, and the semiconductor layer 176 may have a line shape, and may be stacked to contact each other. In the buried interconnection line 170, a relative thickness of each of the first metal layer 172, the second metal layer 174, and the semiconductor layer 176 may be variously changed in some example embodiments. Side surfaces of the first metal layer 172 may be covered with a second interlayer insulating layer 194, and side surfaces of the second metal layer 174 and the semiconductor layer 176 may be covered with a device isolation layer 110.

The semiconductor layer 176 may be directly connected to a second source/drain region 150B to apply an electrical signal to the second source/drain region 150B. The semiconductor layer 176 may be partially recessed by the second source/drain region 150B. However, in some example embodiments, the semiconductor layer 176 may not be recessed, and may be in contact with the second source/drain region 150B through an upper surface thereof.

As illustrated in FIG. 2B, the first metal layer 172 may have a first width W1 in a y direction, and the second metal layer 174 may have a second width W2, which may be narrower than the first width W1 in the y direction. Since the first metal layer 172 may have a relatively large width, resistance of the buried interconnection line 170 may be lowered. In the buried interconnection line 170, a bent portion may be formed between the first metal layer 172 and the second metal layer 174 as the width changes. However, in some example embodiments, the first width W1 and the second width W2 may be substantially the same.

The buried interconnection line 170 may be disposed to overlap the buried insulating layer 108, the active layer 105, and the channel structures 140 in a z-direction. As illustrated in FIG. 2B, in a cross-section in the Y-direction, the buried interconnection line 170 may have side surfaces inclined to decrease in width toward an upper portion thereof. In some example embodiments, side surfaces of the buried interconnection line 170 may be positioned on a straight line with side surfaces of the channel structures 140 and side surfaces of the buried insulating layer 108. For example, the straight line may be a line inclined to increase in width toward the buried interconnection line 170, but example embodiments are not limited thereto. Accordingly, the second width W2 of the second metal layer 174 may be equal to or greater than a third width W3 of a lowermost first channel layer 141. In some example embodiments, the straight line may be a line extending perpendicularly or substantially perpendicularly to the upper surface of the buried interconnection line 170 in the z-direction. Side surfaces of each of the first metal layer 172, the second metal layer 174, and the semiconductor layer 176 may be coplanar or substantially coplanar with each other.

The first metal layer 172 and the second metal layer 174 may include the same or different metals. The first metal layer 172 and the second metal layer 174 may include at least one of, for example, tungsten (W), copper (Cu), aluminum (Al), cobalt (Co), ruthenium (Ru), titanium (Ti), and molybdenum (Mo), but example embodiments are not limited thereto. For example, the first metal layer 172 may include a material having relatively low resistivity, and the second metal layer 174 may include a material having relatively excellent adhesion to the semiconductor layer 176. For example, the first metal layer 172 may include tungsten (W) and/or copper (Cu), and the second metal layer 174 may include at least one of cobalt (Co), ruthenium (Ru), tungsten (W), and titanium (Ti), but example embodiments are not limited thereto. The semiconductor layer 176 may include a highly doped semiconductor material, for example, single crystal or polycrystalline silicon (Si). The semiconductor layer 176 may include, for example, impurities in a concentration in a range of about 1×10¹⁹/cm³ to about 1×10²⁰/cm³, but example embodiments are not limited thereto. When a doping concentration of the semiconductor layer 176 is lower than the above range, resistance may increase, and when a doping concentration of the semiconductor layer 176 is higher than the above range, manufacturing costs may increase.

The buried insulating layer 108 may be disposed on the buried interconnection line 170, and may extend in the X-direction along the buried interconnection line 170. The buried insulating layer 108 may be disposed between the buried interconnection line 170 and the active layer 105 to electrically separate the buried interconnection line 170 from the active layer 105 and the channel structures 140 thereabove. The buried insulating layer 108 may include an insulating material, for example, at least one of silicon oxide, silicon nitride, and silicon oxynitride, but example embodiments are not limited thereto. In some example embodiments, a thickness of the buried insulating layer 108 may be variously changed

The active layer 105 may be disposed on the buried insulating layer 108 to overlap the buried interconnection line 170 and extend in the x direction. The active layer 105 may form an active structure in which a channel region of the transistor is formed, together with the channel structures 140. An upper surface of the active layer 105 may be located on a higher level than an upper surface of the device isolation layer 110, below the gate structures 160. The active layer 105 may be partially recessed or penetrated on both sides of the gate structures 160. First source/drain regions 150A may be disposed in regions in which the active region 105 is recessed, and a second source/drain region 150B may be disposed in a region in which the active layer 105 is penetrated.

The active layer 105 may include a semiconductor material, such as a Group IV semiconductor, a Group III-V compound semiconductor, or a Group II-VI compound semiconductor. For example, the group IV semiconductor may include silicon (Si), germanium (Ge), or silicon-germanium (SiGe). The active layer 105 may be provided as a silicon on insulator (SOI) layer together with the semiconductor layer 176 and the buried insulating layer 108. For example, the active layer 105 may be a single crystal layer, but example embodiments are not limited thereto.

The device isolation layer 110 may be disposed on side surfaces of the buried interconnection line 170, side surfaces of the buried insulating layer 108, and side surfaces of the active layer 105. The device isolation layer 110 may be formed by, for example, a shallow trench isolation (STI) process. In particular, when a plurality of active layers 105 and a plurality of buried interconnection lines 170 are respectively disposed, the device isolation layer 110 may fill spaces between each of the plurality of active layers 105 and spaces between the plurality of buried interconnection lines 170. The device isolation layer 110 may be made of an insulating material. The device isolation layer 110 may be, for example, an oxide, a nitride, a combination thereof, etc.

The channel structures 140 may be disposed on the active region 105 in regions in which the active region 105 intersects the gate structures 160. The channel structures 140 may include first to fourth channel layers 141, 142, 143, and 144, which are two or more channel layers, disposed to be spaced apart from each other in a z direction. The channel structures 140 may be connected to the first and second source/drain regions 150A and 150B. The channel structures 140 may have the same or smaller width as the active layer 105 in the Y-direction, and may have the same or similar width as the gate structures 160 in the X-direction. In a cross-section along the Y-direction, a channel layer disposed therebelow among the first to fourth channel layers 141, 142, 143, and 144 may have the same width as or greater than that of a channel layer disposed thereabove. In some example embodiments, the channel structures 140 may have a reduced width such that side surfaces thereof are positioned below the gate structures 160 in the X-direction.

The channel structures 140 may be made of a semiconductor material, and may include, for example, at least one of silicon (Si), silicon germanium (SiGe), and germanium (Ge), but example embodiments are not limited thereto. The channel structures 140 may be formed of, for example, the same material as the active layer 105. In some example embodiments, the channel structures 140 may include an impurity region located in a region, adjacent to the first and second source/drain regions 150A and 150B. The number and shape of the channel layers constituting one channel structure 140 may be variously changed in some example embodiments.

The gate structures 160 may be disposed on the active region 105 to cross the active region 105 and the buried interconnection line 170 and extend in a second direction, for example, the Y-direction. A channel region of transistors may be formed in the active region 105 and the channel structure 140 intersecting a gate electrode 165 of a gate structure 160. The gate structure 160 may include a gate electrode 165, a gate dielectric layer 162, and gate spacer layers 164. In some example embodiments, the gate structure 160 may further include a capping layer on an upper surface of the gate electrode 165. Alternatively, a portion of a first interlayer insulating layer 192 on the gate structures 160 may be referred to as a gate capping layer.

The gate dielectric layers 162 may be disposed between the active region 105 and the gate electrode 165 and between the channel structure 140 and the gate electrode 165, and may be disposed to cover at least a portion of surfaces of the gate electrode 165. For example, the gate dielectric layers 162 may be disposed to surround all surfaces except for an uppermost surface of the gate electrode 165. The gate dielectric layers 162 may extend between the gate electrode 165 and the gate spacer layers 164, but example embodiments are not limited thereto. The gate dielectric layer 162 may include an oxide, a nitride, a high dielectric constant (high-k) material, etc. The high-k material may be a dielectric material having a dielectric constant, higher than that of silicon oxide (SiO₂). The high-k material may be any one of, for example, aluminum oxide (Al₂O₃), tantalum oxide (Ta₂O₃), titanium oxide (TiO₂), yttrium oxide (Y2O3), zirconium oxide (ZrO₂), zirconium silicon oxide (ZrSiₓO_{y}), hafnium oxide (HfO₂), hafnium silicon oxide (HfSᵢₓO_{y}), lanthanum oxide (La₂O₃), lanthanum aluminum oxide (LaAₗₓO_{y}), lanthanum hafnium oxide (LaH_{fx}O_{y}), hafnium aluminum oxide (HfAₗₓO_{y}), and praseodymium oxide (Pr₂O₃), but example embodiments are not limited thereto. According to some example embodiments, the gate dielectric layer 162 may be formed of a multilayer film.

The gate electrode 165 may include a conductive material, and may include, for example, a metal nitride such as a titanium nitride film (TiN), a tantalum nitride film (TaN), or a tungsten nitride film (WN), and/or a metal material such as aluminum (Al), tungsten (W), molybdenum (Mo), or the like, or a semiconductor material such as doped polysilicon, but example embodiments are not limited thereto. According to some example embodiments, the gate electrode 165 may be formed of two or more multi-layers.

The gate spacer layers 164 may be disposed on both side surfaces of the gate electrode 165 above the channel structure 140. The gate spacer layers 164 may insulate the first and second source/drain regions 150A and 150B and the gate electrodes 165 from each other. According to some example embodiments, a shape of upper ends of the gate spacer layers 164 may be variously changed, and the gate spacer layers 164 may have a multi-layer structure. The gate spacer layers 164 may be formed of oxide, nitride, oxynitride, etc., such as, e.g., a low-k film.

The first and second source/drain regions 150A and 150B may be respectively disposed to contact the channel structures 140 on both sides of the gate structures 160. The second source/drain region 150B may be a source/drain region connected to the buried interconnection line 170 to receive power. The first source/drain regions 150A and the second source/drain regions 150B may have different depths.

Lower ends of the first and second source/drain regions 150A and 150B may be located at different levels. A level of a lower end of the second source/drain region 150B may be lower than a level of lower ends of the first source/drain regions 150A. The first source/drain regions 150A may be disposed in recess regions partially recessed from an upper portion of the active layer 105. The second source/drain region 150B may be disposed in a region in which an upper portion of the semiconductor layer 176 of the buried interconnection line 170 is partially recessed through the active layer 105 and the buried insulating layer 108. The first source/drain regions 150A may be spaced apart from the buried interconnection line 170, and the second source/drain region 150B may be connected to the buried interconnection line 170. Lower surfaces of the first source/drain regions 150A may be in contact with the active layer 105, and a lower surface of the second source/drain regions 150B may be in contact with the semiconductor layer 176.

Upper surfaces of the first and second source/drain regions 150A and 150B may be positioned at a level, equal to or similar to that of lower surfaces of uppermost portions of the gate structures 160 on the channel structures 140, and a level of upper surfaces of the source/drain regions 150A and 150B may be variously changed in some example embodiments. The first and second source/drain regions 150A and 150B may have a polygonal shape or an elliptical shape, as illustrated in FIG. 2C, in a cross-section along the Y-direction, but example embodiments are not limited thereto. In some example embodiments, the first and second source/drain regions 150A and 150B may be connected to or merged with each other on two or more active layers 105 adjacent in the Y-direction, to form one source/drain region, respectively. The first and second source/drain regions 150A and 150B may include a semiconductor material, and may further include impurities.

The inner spacer layers 130 may be disposed in parallel with the gate electrodes 165 between the first to fourth channel layers 141, 142, 143, and 144 in the z direction. The gate electrodes 165 may be stably spaced apart from the first and second source/drain regions 150A and 150B by the inner spacer layers 130 to be electrically separated from each other. The inner spacer layers 130 may have a shape in which side surfaces facing the gate electrodes 165 are convexly rounded inwardly toward the gate electrode 165, but example embodiments are not limited thereto. The inner spacer layers 130 may be made of oxide, nitride, oxynitride, etc., such as, e.g., a low-k film. However, in some example embodiments, the inner spacer layers 130 may be omitted.

The first interlayer insulating layer 192 may be disposed to cover upper surfaces of the first and second source/drain regions 150A and 150B and the gate structures 160, and to cover an upper surface of the device isolation layer 110. The second interlayer insulating layer 194 may be disposed to cover a lower surface of the buried interconnection line 170 and a lower surface of the device isolation layer 110. The first and second interlayer insulating layers 192 and 194 may include at least one of oxide, nitride, oxynitride, etc., and may include, for example, a low-k material. In some example embodiments, each of the first and second interlayer insulating layers 192 and 194 may include a plurality of insulating layers.

The contact plugs 180 may be disposed on the buried interconnection line 170. The contact plugs 180 may penetrate through the first interlayer insulating layer 192 to be connected to the first source/drain regions 150A, and may apply an electrical signal to the first source/drain regions 150A. The contact plugs 180 may have side surfaces inclined to decrease in width toward the buried interconnection line 170 according to an aspect ratio, but example embodiments are not limited thereto. The contact plugs 180 may extend from an upper portion, for example, downwardly of a lower surface of the fourth channel layers 144 in an uppermost portion of each of the channel structures 140, but example embodiments are not limited thereto. In some example embodiments, the contact plugs 180 may be disposed to contact along upper surfaces of the first source/drain regions 150A without recessing the first source/drain regions 150A. The contact plugs 180 may be further disposed to be connected to the gate electrodes 165 in a region not shown.

The vias 185 may be disposed on a lower surface of the buried interconnection line 170, below the buried interconnection line 170. The vias 185 may penetrate through a second interlayer insulating layer 194 to be connected to a first metal layer 172 of the buried interconnection line 170, and may apply an electrical signal to the buried interconnection line 170. The vias 185 may have side surfaces inclined to decrease in width toward the buried interconnection line 170 according to an aspect ratio, but example embodiments are not limited thereto.

The contact plugs 180 and/or the vias 185 may include a metal silicide layer disposed at a lower end and an upper end thereof, and may further include a barrier layer disposed on sidewalls and on the metal silicide layer. The barrier layer may include, for example, a metal nitride such as a titanium nitride layer (TiN), a tantalum nitride layer (TaN), a tungsten nitride layer (WN), etc. The contact plugs 180 and the vias 185 may include, for example, a metal material such as aluminum (Al), tungsten (W), or molybdenum (Mo), but example embodiments are not limited thereto. In some example embodiments, the number and a dispositional form of conductive layers constituting each of the contact plugs 180 and the vias 185 may be variously altered.

The interconnection lines 187 may be disposed on lower surfaces of the vias 185 to be connected to the vias 185. The interconnection lines 187 may form a power delivery network (PDN) together with the vias 185. The interconnection lines 187 may include, for example, a metal material such as aluminum (Al), tungsten (W), molybdenum (Mo), etc. In example embodiments, an interconnection structure including an interconnection line may be further disposed on the contact plugs 180.

The semiconductor device 100 may be packaged with the structure of FIGS. 2A to 2C inverted so that the interconnection lines 187 are located thereabove, but a packaging form of the semiconductor device 100 is not limited thereto. Since the semiconductor device 100 includes the buried interconnection line 170 disposed below the first and second source/drain regions 150A and 150B, the degree of integration may be improved. Since the buried interconnection line 170 extends in a form of a line and includes a semiconductor layer 176 in contact with a second metal layer 174, and is connected to a second source/drain region 150B through the semiconductor layer 176 without a separate contact plug, the resistance may be reduced or minimized

In the description of some example embodiments below, descriptions overlapping with those described above with reference to FIGS. 1 to 2C may be omitted.

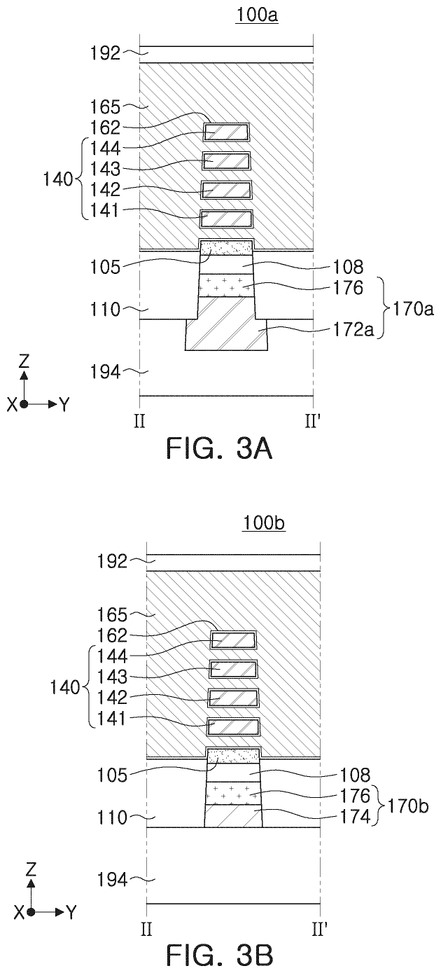

FIGS. 3A and 3B are schematic cross-sectional views illustrating semiconductor devices according to some example embodiments. FIGS. 3a and 3b illustrate a region corresponding to FIG. 2B.

Referring to FIG. 3A, in a semiconductor device 100a, a buried interconnection line 170a may include a metal layer 172a and a semiconductor layer 176. Unlike the example embodiment of FIGS. 2A to 2C, the buried interconnection line 170a may include one metal layer 172a. The metal layer 172a of the present example embodiment may have a shape including the first metal layer 172 and the second metal layer 174 of the example embodiment of FIG. 2B. Accordingly, in a cross-section along the Y-direction, the metal layer 172a may have a bent portion as a width thereof is changed on both side surfaces.

Referring to FIG. 3B, in the semiconductor device 100b, the buried interconnection line 170b may include a metal layer 174 and a semiconductor layer 176. The buried interconnection line 170b may have a shape in which the first metal layer 172 in the example embodiment of FIGS. 2A to 2C is omitted. Accordingly, the buried interconnection line 170b may not have a bent portion on a side surface thereof.

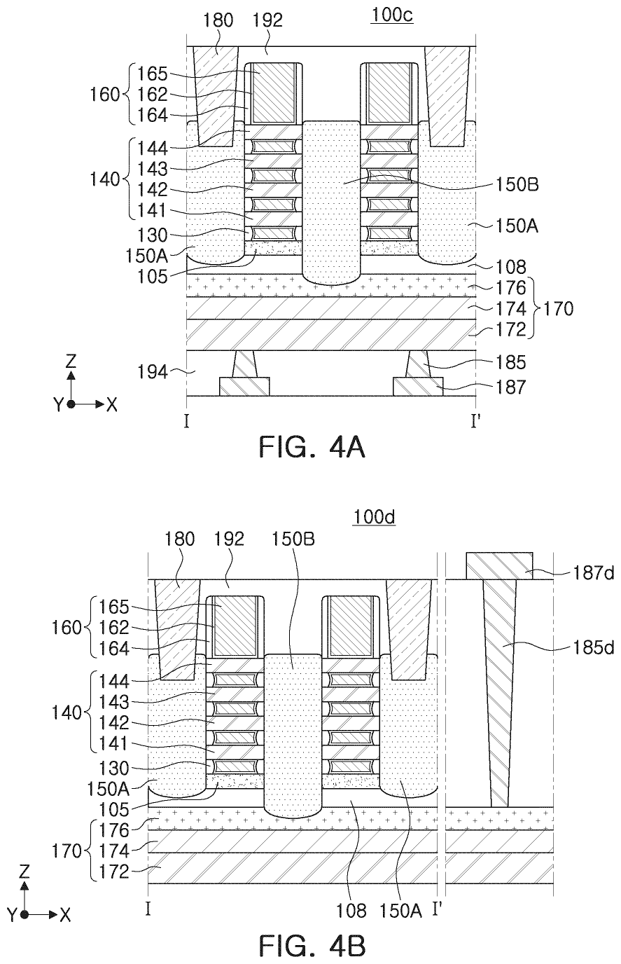

FIGS. 4A and 4B are schematic cross-sectional views illustrating semiconductor devices according to some example embodiments. FIGS. 4a and 4b illustrates a region corresponding to FIG. 2A.

Referring to FIG. 4A, in the semiconductor device 100c, a position of lower ends of the first source/drain regions 150A may be different from that in the example embodiment of FIG. 2A. The first source/drain regions 150A may penetrate through the active layer 105. Lower ends of the first source/drain regions 150A may be located in the buried insulating layer 108, or located on an upper surface of the buried insulating layer 108. Accordingly, the active layer 105 may not continuously extend along the X-direction, but may be disposed only below the channel structures 140. According to the description, the active layer 105 of the present example embodiment may be referred to as a lowermost channel layer of the channel structure 140. In some example embodiments, a level of lower ends of the first source/drain regions 150A may be changed within a range in which the first source/drain regions 150A are disposed to be spaced upwardly of the buried interconnection line 170.

Referring to FIG. 4B, in the semiconductor device 100d, a dispositional form of vias 185d and interconnection lines 187d may be different from that of the example embodiment of FIG. 2A. The vias 185d and the interconnection lines 187d may be disposed on the buried interconnection line 170 rather than below the buried interconnection line 170. For example, the vias 185d may be disposed to penetrate through the first interlayer insulating layer 192 and be connected to the semiconductor layer 176 of the buried interconnection line 170 in an outer region in which transistors are not disposed. The interconnection lines 187d may be disposed on the vias 185d.

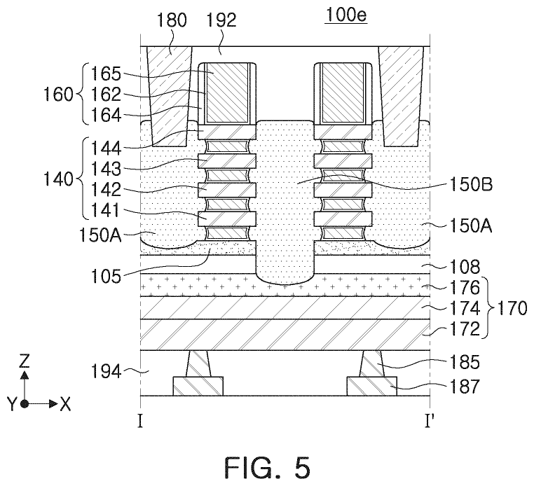

FIG. 5 is a schematic cross-sectional view illustrating a semiconductor device according to some example embodiments.

Referring to FIG. 5, a semiconductor device 100e may not include an inner spacer layer 130, unlike the example embodiment of FIG. 2A. In some example embodiments, the first and second source/drain regions 150A and 150B may have a shape expanding to a region in which the inner spacer layers 130 are omitted. The gate electrodes 165 may be spaced apart from the source/drain regions 150 by the gate dielectric layers 162. In another example embodiment, the first and second source/drain regions 150A and 150B do not expand to a region in which the inner spacer layers 130 are omitted, and the gate electrodes 165 may be disposed to expand along the x direction.

According to this structure, the inner spacer layer 130 may be omitted, so that the first and second source/drain regions 150A and 150B may have improved crystallinity when the first and second source/drain regions 150A and 150B are grown. In some example embodiments, the inner spacer layer 130 may be omitted only in some devices of the semiconductor device 100e. For example, when SiGe is used for the first and second source/drain regions 150A and 150B in the pFET, the inner spacer layer 130 may be selectively omitted only in the pFET in order to improve crystallinity of SiGe.

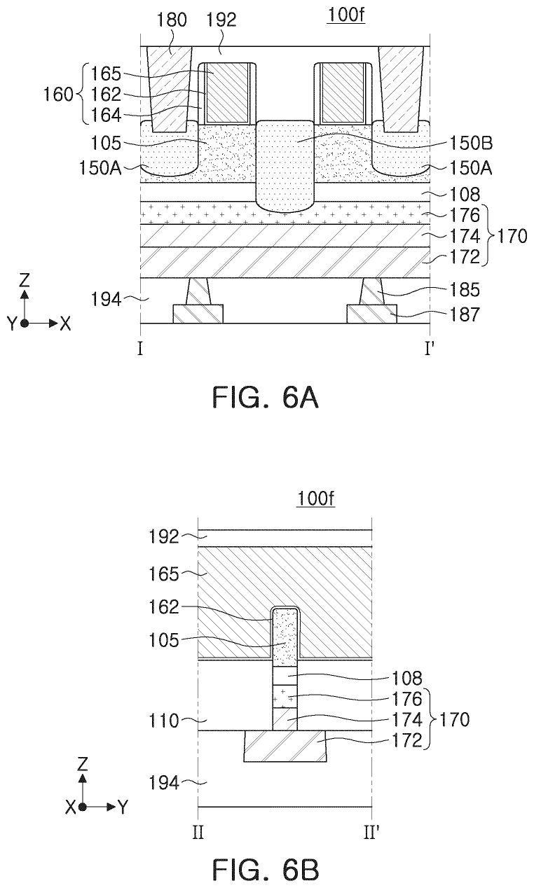

FIGS. 6A and 6B are cross-sectional views illustrating semiconductor devices according to some example embodiments. FIGS. 6A and 6B illustrate cross-sections corresponding to FIGS. 2A and 2B, respectively.

Referring to FIGS. 6A and 6B, a semiconductor device 100f may not include the channel structures 140, unlike the example embodiment of FIGS. 1 to 2C, and accordingly, a disposition of the gate structures 160 may be different from that in the above embodiment.

The semiconductor device 100f may include FinFETs that do not include a separate channel layer. In the semiconductor device 100f, a channel region of transistors may be limited to the active layer 105 having a fin structure, which is an active structure. Separate channel layers may not be interposed in the gate electrodes 165. However, other descriptions of the gate electrodes 165 and the description of the buried interconnection line 170 may be equally applied to the descriptions in the example embodiments of FIGS. 1 to 2C. Such a semiconductor device 100f may be additionally disposed in one region of the semiconductor device of other example embodiments.

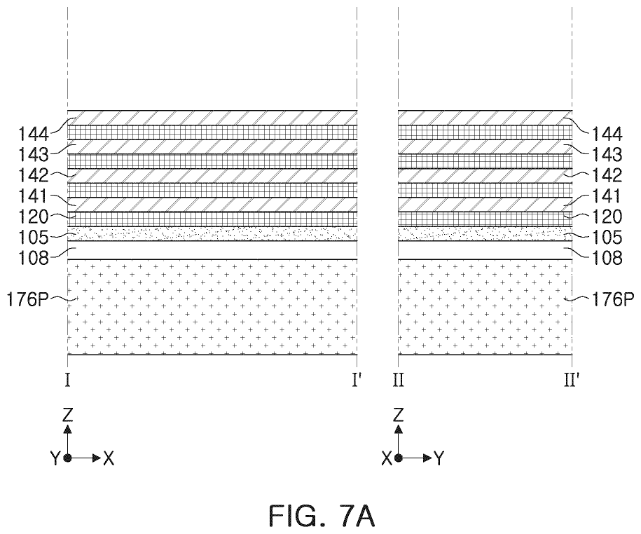

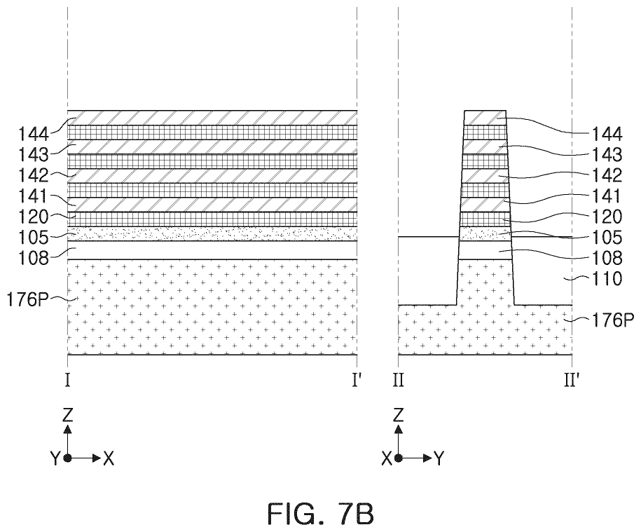

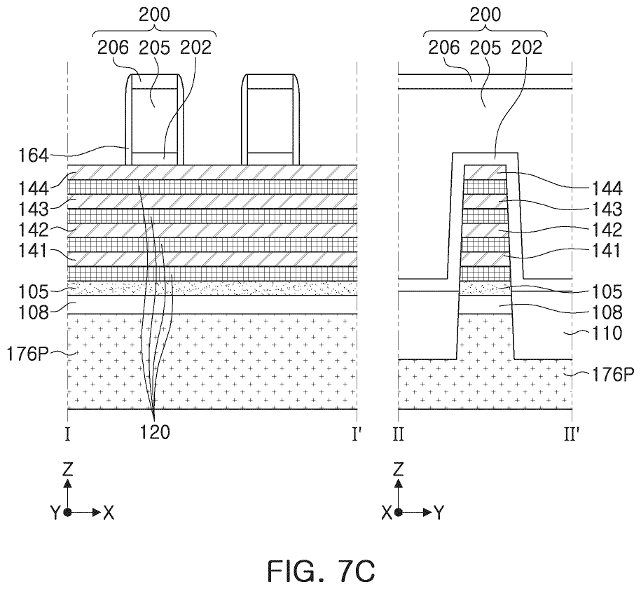

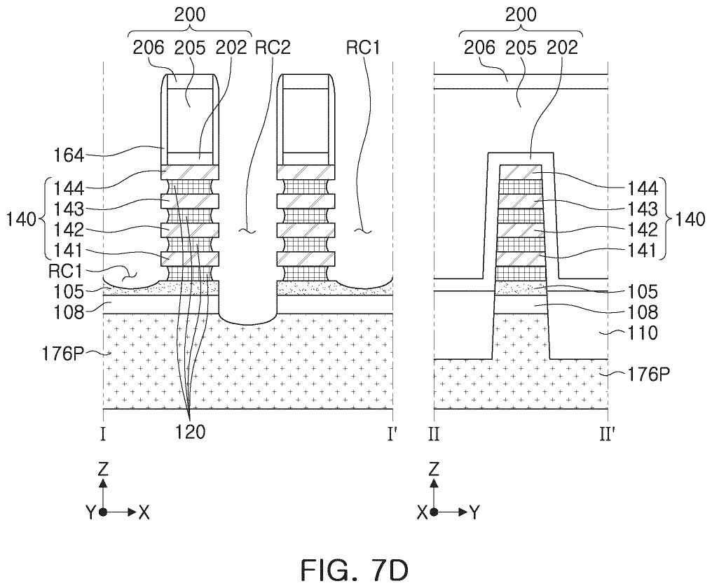

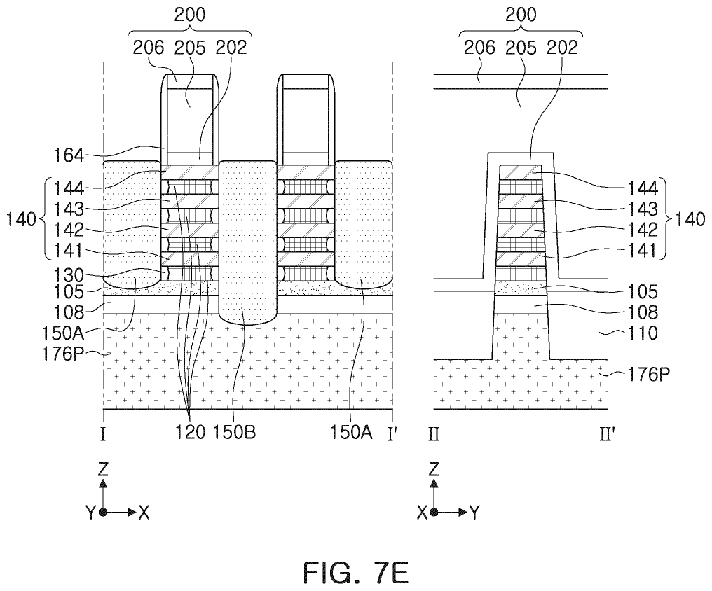

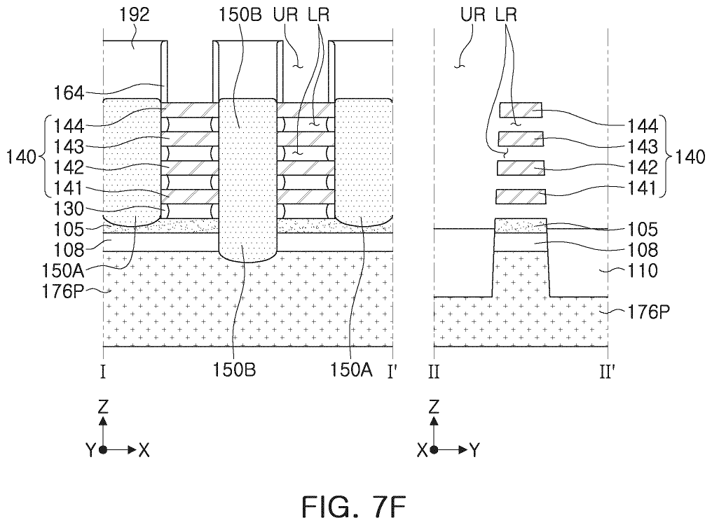

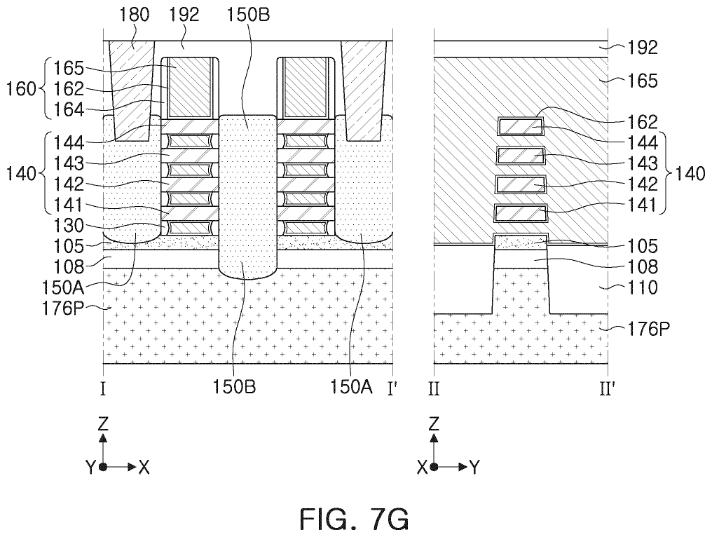

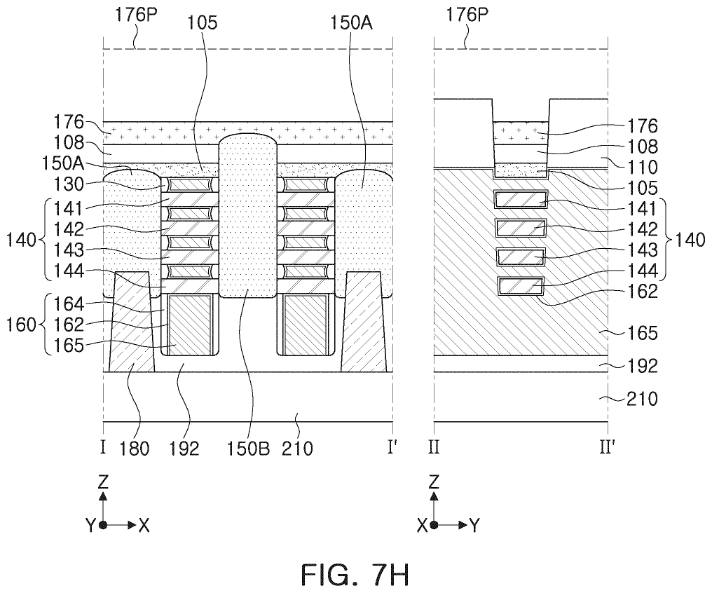

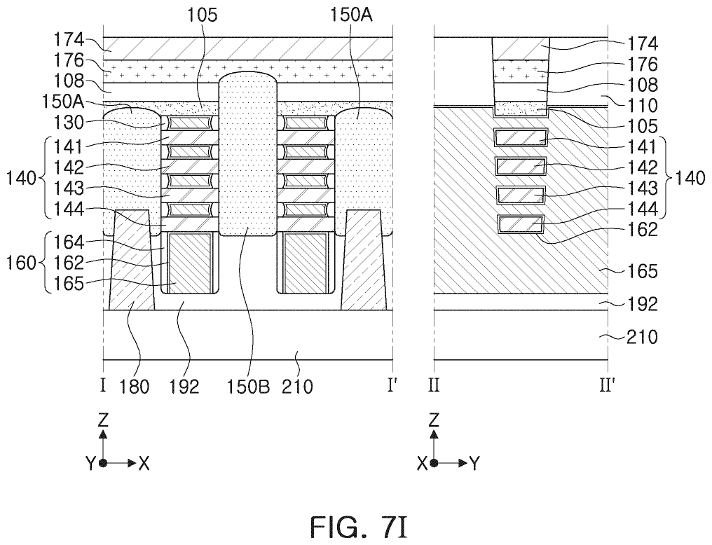

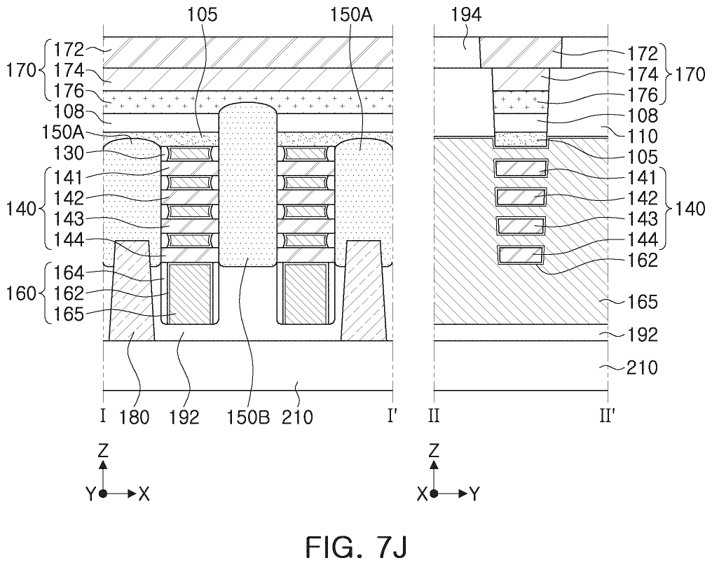

FIGS. 7A to 7J are diagrams illustrating a process sequence in order to explain a method of manufacturing a semiconductor device according to some example embodiments. FIGS. 7A to 7J illustrate an example embodiment of a manufacturing method for manufacturing the semiconductor device of FIGS. 1 to 2C, and cross-sections along cutting lines I-I′ and II-II′ of FIG. 1 are respectively illustrated together.

Referring to FIG. 7A, sacrificial layers 120 and first to fourth channel layers 141, 142, 143, and 144 may be alternately stacked on a stacked structure including a substrate semiconductor layer 176P, a buried insulating layer 108, and an active layer 105.

In some example embodiments, the stacked structure including the substrate semiconductor layer 176P, the buried insulating layer 108, and the active layer 105 may be provided as one substrate. The stacked structure may be provided as, for example, an SOI substrate. The substrate semiconductor layer 176P may be a layer forming a semiconductor layer 176 of the buried interconnection line 170 of FIGS. 2A and 2B through a subsequent process. The substrate semiconductor layer 176P may include impurities doped at a high concentration in at least a region adjacent to the buried insulating layer 108. For example, in the region, an impurity concentration in the substrate semiconductor layer 176P may be higher than an impurity concentration in the active layer 105. The substrate semiconductor layer 176P and the active layer 105 may be a single crystal semiconductor layer, but example embodiments are not limited thereto. In some example embodiments, the buried insulating layer 108 and the active layer 105 may be formed by performing deposition on the substrate semiconductor layer 176P. In some example embodiments, the active layer 105 may be a polycrystalline layer.

The sacrificial layers 120 may be replaced by the gate dielectric layer 162 and the gate electrode 165 as illustrated in FIGS. 2A and 2B through a subsequent process. The sacrificial layers 120 may be made of a material having etch selectivity with respect to first to fourth channel layers 141, 142, 143, and 144, respectively. The first to fourth channel layers 141, 142, 143, and 144 may include a material, different from that of the sacrificial layers 120. The sacrificial layers 120 and the first to fourth channel layers 141, 142, 143, and 144 may include, for example, at least one of silicon (Si), silicon germanium (SiGe), and germanium (Ge), but example embodiments are not limited thereto. The semiconductor material may include different materials, and may or may not include impurities. For example, the sacrificial layers 120 may include silicon germanium (SiGe), and the first to fourth channel layers 141, 142, 143, and 144 may include silicon (Si).

The sacrificial layers 120 and the first to fourth channel layers 141, 142, 143, and 144 may be formed by performing an epitaxial growth process from the stacked structure. Each of the sacrificial layers 120 and the first to fourth channel layers 141, 142, 143, and 144 may have a thickness in a range of about 1 A to about 100 nm, but example embodiments are not limited thereto. The number of layers of the channel layers alternately stacked with the sacrificial layers 120 may be variously changed in example embodiments.

Referring to FIG. 7B, an active structure may be formed by removing a portion of the stacked structure, the sacrificial layers 120, and the first to fourth channel layers 141, 142, 143, and 144, and a device isolation layer 110 may be formed.

The active structure may include an active layer 105, sacrificial layers 120, and first to fourth channel layers 141, 142, 143, and 144. The active structure may be formed in a form of a line extending in one direction, for example, an X-direction, and may be formed to be spaced apart from an active structure, adjacent in the Y-direction. In the present step, side surfaces of the active structure in the Y-direction may be defined, and the side surfaces may be coplanar or substantially coplanar with each other and positioned on a straight line.

In a region in which each of the active layer 105, the sacrificial layers 120, and the first to fourth channel layers 141, 142, 143, and 144 are partially removed, a device isolation layer 110 may be formed by filling an insulating material and then removing the insulating material such that the active layer 105 protrudes. An upper surface of the device isolation layer 110 may be formed, lower than the upper surface of the active layer 105.

Referring to FIG. 7C, sacrificial gate structures 200 and gate spacer layer 164 may be formed on the active structure.

The sacrificial gate structures 200 may be sacrificial layers formed in a region in which the gate dielectric layer 162 and the gate electrodes 165 are disposed above the channel structures 140 as illustrated in FIGS. 2A and 2B through a subsequent process. The sacrificial gate structure 200 may include first and second sacrificial gate layers 202 and 205 and a mask pattern layer 206, which may be sequentially stacked. The first and second sacrificial gate layers 202 and 205 may be patterned using a mask pattern layer 206. The first and second sacrificial gate layers 202 and 205 may be an insulating layer and a conductive layer, respectively, but are not limited thereto, and in some example embodiments, the first and second sacrificial gate layers 202 and 205 may be formed as one layer. For example, the first sacrificial gate layer 202 may include silicon oxide, and the second sacrificial gate layer 205 may include polysilicon. The mask pattern layer 206 may include silicon oxide and/or silicon nitride, but example embodiments are not limited thereto. The sacrificial gate structures 200 may have a line shape extending in one direction intersecting the active structure. The sacrificial gate structures 200 may extend, for example, in the Y-direction and may be disposed to be spaced apart from each other in the X-direction.

Gate spacer layers 164 may be formed on both sidewalls of the sacrificial gate structures 200. The gate spacer layers 164 may be made of a low-k material, and may include, for example, at least one of SiO, SiN, SiCN, SiOC, SiON, and SiOCN, but example embodiments are not limited thereto.

Referring to FIG. 7D, the exposed sacrificial layers 120 and the first to fourth channel layers 141, 142, 143, and 144 may be partially removed between the sacrificial gate structures 200, and the first and second recess regions RC1 and RC2 may be formed.

A portion of the exposed sacrificial layers 120 and the first to fourth channel layers 141 , 142 , 143 and 144 may be removed, by using the sacrificial gate structures 200 and the gate spacer layers 164 as masks, to form first and second recess regions RC1 and RC2. The first and second recess regions RC1 and RC2 may be formed to have different depths.

The first recess regions RC1 may be formed to expose the active layer 105. The second recess region RC2 may be formed to penetrate the active layer 105 and the buried insulating layer 108 to expose the substrate semiconductor layer 176P. For example, after forming the first recess regions RC1, a separate mask layer for exposing a region in which the second recess region RC2 is to be formed is formed, and then the active layer 105 and the buried insulating layer 108 may be further removed from the region to form a second recess region RC2. In the present step, the first to fourth channel layers 141, 142, 143, and 144 may form channel structures 140 having a limited length in the X-direction.

Next, the sacrificial layers 120 exposed through the first and second recess regions RC1 and RC2 may be partially removed from side surfaces thereof. The sacrificial layers 120 may be selectively etched with respect to the channel structures 140 by, for example, a wet etching process, and may be removed to a specified depth from the side surface along the x direction. The sacrificial layers 120 may have inwardly concave side surfaces by the side etching as described above. However, the shape of the side surfaces of the sacrificial layers 120 is not limited to those illustrated.

Referring to FIG. 7E, inner spacer layers 130 and first and second source/drain regions 150A and 150B may be formed.

The internal spacer layers 130 may be formed by filling a region from which sacrificial layers 120 are removed with an insulating material and then removing the insulating material deposited on an outside of the channel structures 140. The inner spacer layers 130 may be formed of the same material as the gate spacer layers 164, but example embodiments are not limited thereto. For example, the inner spacer layers 130 may include at least one of SiN, SiCN, SiOCN, SiBCN, and SiBN.

Next, the first and second source/drain regions 150A and 150B may be formed by being grown, for example, a selective epitaxial process from side surfaces of the active layer 105, the substrate semiconductor layer 176P, and the channel structures 140. The first and second source/drain regions 150A and 150B may include impurities by in-situ doping, and include a plurality of layers having different doping elements and/or doping concentrations.

Referring to FIG. 7F, a first interlayer insulating layer 192 may be formed, and sacrificial layers 120 and sacrificial gate structures 200 may be removed.

The first interlayer insulating layer 192 may be formed by forming an insulating film covering the sacrificial gate structures 200 and the first and second source/drain regions 150A and 150B and performing a planarization process.

The sacrificial layers 120 and the sacrificial gate structures 200 may be selectively removed with respect to gate spacer layers 164, a first interlayer insulating layer 192, channel structures 140, and inner spacer layers 130. First, the sacrificial gate structures 200 may be removed to form upper gap regions UR, and then the sacrificial layers 120 exposed through the upper gap regions UR may be removed to form lower gap regions LR. For example, when the sacrificial layers 120 include silicon germanium (SiGe) and the channel structures 140 include silicon (Si), the sacrificial layers 120 may be selectively removed by performing a wet etching process by using peracetic acid as an etchant. During the removal process, the first and second source/drain regions 150A and 150B may be protected by the first interlayer insulating layer 192 and the inner spacer layers 130.

Referring to FIG. 7G, gate structures 160 may be formed, and contact plugs 180 may be formed.

The gate structures 160 may be formed to fill upper gap regions UR and lower gap regions LR. The gate dielectric layers 162 may be formed to conformally cover inner surfaces of the upper gap regions UR and the lower gap regions LR. After the gate electrode 165 is formed to fill (e.g., completely fill) the upper gap regions UR and the lower gap regions LR, it may be removed from the top in the upper gap regions UR to a specified depth together with the gate dielectric layers 162 and the gate spacer layers 164. Accordingly, the gate structures 160 including the gate dielectric layer 162, the gate electrode 165, and the gate spacer layers 164 may be formed.

Next, a first interlayer insulating layer 192 may be further formed on the gate structures 160, and the first interlayer insulating layer 192 may be partially removed to form contact holes for exposing the first source/drain regions 150A. A conductive material may be buried in the contact holes. For example, after depositing a material constituting a barrier layer in the contact holes, a silicide process may be performed to form a metal-semiconductor compound layer such as a silicide layer in a lower end portion. Next, a conductive material may be deposited to fill the contact holes to form contact plugs 180. Although not illustrated, interconnection structures connected to the contact plugs 180 may be further formed on the contact plugs 180.

Referring to FIG. 7H, the entire formed structure may be bonded to a carrier substrate 210, and a semiconductor layer 176 may be formed by partially removing a substrate semiconductor layer 176P.

First, the entire structure formed with reference to FIGS. 7A to 7G may be flip-bonded to the carrier substrate 210. Accordingly, the entire structure may be turned upside down, whereby the substrate semiconductor layer 176P may be exposed upwardly.

The semiconductor layer 176 may be formed by thinning the substrate semiconductor layer 176P by removing the semiconductor layer 176P from an upper surface thereof to a specified thickness. The substrate semiconductor layer 176P may be selectively removed with respect to the device isolation layer 110 through an etching process. The upper surface of the semiconductor layer 176 may be formed to be lower than the upper surface of the device isolation layer 110. Accordingly, a recess region may be formed in the device isolation layer 110 to expose the upper surface of the semiconductor layer 176.

Referring to FIG. 7I, a second metal layer 174 may be formed in the recess region of the device isolation layer 110.

The second metal layer 174 may be formed to fill the recess region by depositing a metal material and planarizing the same. An upper surface of the second metal layer 174 may be coplanar or substantially coplanar with an upper surface of the device isolation layer 110. As described above, since the semiconductor layer 176 and the second metal layer 174 are formed in the recess region of the device isolation layer 110, they may be formed to be self-aligned to the channel structures 140, the active layer 105, and the buried insulating layer 108 without a separate patterning process.

Referring to FIG. 7J, a first metal layer 172 and a second interlayer insulating layer 194 may be formed.

First, a second interlayer insulating layer 194 may be formed on a second metal layer 174, and the second interlayer insulating layer 194 may be patterned to expose the second metal layer 174. Next, a first metal layer 172 may be formed in a region in which the second interlayer insulating layer 194 is removed by patterning. Accordingly, a buried interconnection line 170 including the first metal layer 172, the second metal layer 174, and the semiconductor layer 176 may be formed. However, in some example embodiments, the first metal layer 172 may be first formed and the second interlayer insulating layer 194 may be formed.

Next, referring to FIGS. 2A and 2B together, a second interlayer insulating layer 194 may be further formed, and vias 185 and upper interconnection lines 187 may be formed, and a carrier substrate 210 may be removed.

An interconnection structure may be further formed on the interconnection lines 187. Accordingly, the semiconductor device 100 of FIGS. 2A to 2C may be manufactured. The semiconductor device 100 may be packaged with the buried interconnection line 170 positioned thereabove, but an example embodiment thereof is not limited thereto as shown in FIG. 7J.

As set forth above, according to example embodiments of the inventive concepts, by disposing a buried interconnection line to be connected to a portion of source/drain regions through a line-shaped semiconductor layer, a semiconductor device having an improved degree of integration and improved electrical characteristics may be provided.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

While example embodiments have been shown and described above modifications and variations could be made without departing from the scope of the inventive concepts.

What is claimed is:

1. A semiconductor device, comprising:
a buried interconnection line extending in a first direction;
a gate electrode extending in a second direction intersecting the buried interconnection line, the gate electrode on the buried interconnection line;
channel layers spaced apart from each other in a third direction perpendicular to the first direction and the second direction, the channel layers on the buried interconnection line and surrounded by the gate electrode, the buried interconnection line including a metal layer and a semiconductor layer stacked in the third direction;
a buried insulating layer between the channel layers and the buried interconnection line;
a first source/drain region and a second source/drain region, the first and second source/drain regions in contact with the channel layers on both sides of the gate electrode, and the second source/drain region penetrating through the buried insulating layer and in contact with the semiconductor layer of the buried interconnection line;
a contact plug on the first source/drain region, and connected to the first source/drain region; and
a via below the buried interconnection line, and connected to the buried interconnection line.

2. The semiconductor device of claim 1, wherein, in the buried interconnection line, each of the metal layer and the semiconductor layer has a line shape extending in the first direction.

3. The semiconductor device of claim 1, wherein a level of a lower end of the second source/drain region is lower than a level of a lower end of the first source/drain region.

4. The semiconductor device of claim 1, wherein the first source/drain region is spaced apart from the buried interconnection line.

5. The semiconductor device of claim 1, wherein the metal layer of the buried interconnection line comprises a first metal layer, and a second metal layer between the first metal layer and the semiconductor layer.

6. The semiconductor device of claim 5, wherein the first metal layer has a first width in the second direction, and the second metal layer has a second width narrower than the first width in the second direction.

7. The semiconductor device of claim 5, wherein side surfaces of the second metal layer in the second direction are coplanar with side surfaces of the semiconductor layer in the second direction.

8. The semiconductor device of claim 1, wherein, in the second direction, the buried interconnection line has a first width, and the channel layers have a second width equal to or narrower than the first width.

9. The semiconductor device of claim 1, wherein the buried interconnection line has inclined side surfaces and the buried interconnection line decreases in width toward the first and second source/drain regions.

10. The semiconductor device of claim 1, further comprising:
an active layer on the buried insulating layer, overlapping the buried interconnection line and extending in the first direction.

11. The semiconductor device of claim 10, wherein a lower surface of the first source/drain region is in contact with the active layer.

12. The semiconductor device of claim 1, further comprising:
a device isolation layer covering at least a portion of side surfaces of the buried interconnection line.

13. The semiconductor device of claim 1, wherein the contact plug is above the buried interconnection line, and
each of the contact plug and the via have inclined side surfaces, and each of the contact plug and the via decrease in width toward the buried interconnection line.

14. A semiconductor device, comprising:
a buried interconnection line extending in a first direction;
a buried insulating layer on the buried interconnection line;
an active structure on the buried insulating layer;
a gate electrode extending in a second direction intersecting the active structure, the gate electrode on the buried insulating layer; and
a first source/drain region and a second source/drain region, the first and second source/drain regions on both sides of the gate electrode in regions where the active structure is recessed, the buried interconnection line including a semiconductor layer extending in the first direction and in contact with the second source/drain region.

15. The semiconductor device of claim 14, wherein the first source/drain region has a depth different from a depth of the second source/drain region.

16. The semiconductor device of claim 14, wherein the second source/drain region penetrates through the buried insulating layer and is connected to the semiconductor layer of the buried interconnection line.

17. The semiconductor device of claim 14, wherein the semiconductor layer of the buried interconnection line has a single crystal structure.

18. The semiconductor device of claim 14, wherein the buried interconnection line further comprises a metal layer in contact with the semiconductor layer and extending in the first direction.

19. A semiconductor device, comprising:
a buried interconnection line extending in a first direction;
a buried insulating layer on the buried interconnection line;
a gate electrode extending in a second direction intersecting the first direction, the gate electrode on the buried insulating layer;
channel layers spaced apart from each other in a third direction perpendicular to the first direction and the second direction, the channel layers on the buried insulating layer and surrounded by the gate electrode; and
source/drain regions on both sides of the gate electrode, the buried interconnection line overlapping the channel layers in the third direction, and connected to a portion of the source/drain regions below the source/drain regions.

20. The semiconductor device of claim 19, wherein side surfaces of the channel layers in the second direction and side surfaces of the buried interconnection line in the second direction are on a straight line.
